(19) United States
(12) Patent Application Publication
(10) Pub. No.: US 2010/0304025 A1
(43) Pub. Date: Dec. 2, 2010

(54) DEPOSITION APPARATUS AND METHOD OF CONTROLLING THE SAME

(75) Inventors: Min-Jeong Hwang, Yongin-City (KR); You-Min Cha, Yongin-City (KR); Won-Seok Cho, Yongin-City (KR); Jae-Mork Park, Yongin-City (KR); Jae-Wan Park, Yongin-City (KR); Jae-Hong Ahn, Yongin-City (KR)

Correspondence Address: ROBERT E. BUSHNELL & LAW FIRM, 2029 K STREET NW, SUITE 600, WASHINGTON, DC, 20006-1004, US

(73) Assignee: SAMSUNG MOBILE DISPLAY CO., LTD., Yongin-City (KR)

(21) Appl. No.: 12/770,175

(22) Filed: Apr. 29, 2010

(30) Foreign Application Priority Data
Jun. 2, 2009 (KR) 10-2009-0048648

(51) Int. Cl. C23C 16/44; C23C 16/00

(52) U.S. Cl. 427/255.7; 118/719

(57) ABSTRACT

A deposition apparatus including a plurality of reaction chambers, and a method of controlling the deposition apparatus. The deposition apparatus includes a first chamber to deposit a first deposition material onto a deposition body, a second chamber to deposit a second and different deposition material onto the deposition body, a third chamber to deposit the first deposition material onto the deposition body, a transfer chamber connected to the first through third chambers, the transfer chamber to transfer the deposition body to ones of the first through third chambers and a control unit to transport the deposition body from the transfer chamber to ones of the first through third chambers.

### CLAIM OF PRIORITY

This application makes reference to, incorporates the same herein, and claims all benefits accruing under 35 U.S.C. §119 from an application earlier filed in the Korean Intellectual Property Office on 2 Jun. 2009 and there duly assigned Serial no. 10-2009-0048648

### BACKGROUND OF THE INVENTION

1. Field of the Invention

An aspect of the present invention relates to a deposition apparatus having a plurality of reaction chambers, and a method of controlling the deposition apparatus.

2. Description of the Related Art

With the recent rapid development of the information technology and the expansion of the market thereof, flat panel displays are replacing larger cathode ray tube (CRT) display devices. Examples of the flat panel displays are liquid crystal displays, plasma display panels, organic light emitting diode displays, etc.

Among these, the organic light emitting diode displays have a high response speed and a low power consumption compared to conventional liquid crystal devices, are lightweight, and do not require a backlight unit. Thus the organic light emitting diode displays can be made super-slim, while having high luminance, and thus are being noticed as display devices of the next-generation.

An organic light emitting diode includes an anode layer, an organic thin film layer, and a cathode layer sequentially disposed on a substrate. As a voltage is applied between the anode layer and the cathode layer, a predetermined difference in energy is generated in the organic thin film layer, thereby emitting light. Wavelengths of the generated light can be adjusted according to the amount of the dopants in an organic material of the organic light emitting diode, and thus full color representation is possible.

In more detail, the organic light emitting diode has a structure in which an anode layer, a hole injection layer (HIL), a hole transfer layer (HTL), an emission layer (EML), an electron transfer layer (ETL), an electron injection layer (EIL), and a cathode layer are sequentially stacked on a substrate. Also, the EML can be classified into a red EML, a green EML, and a blue EML, and a hole blocking layer (HBL) can be selectively arranged between the EML and the ETL.

The layers are formed on the substrate by using, for example, a vacuum deposition technique, an ion-plating technique, a sputtering technique, a chemical vapor deposition (CVD) technique, etc. In detail, the vacuum deposition technique is used to form an organic layer and a cathode layer of the organic light emitting diode. In the vacuum deposition technique, a substrate is mounted in a vacuum chamber and gaseous deposition material enters the chamber and deposits onto a surface of the substrate.

A deposition apparatus for manufacturing an organic light emitting diode display includes at least one cluster structure. The cluster structure includes a plurality of reaction chambers for deposition of materials onto a deposition body (or substrate), arranged around a transfer chamber that transports the deposition body. The reaction chambers respectively include different deposition sources in order to deposit different deposition layers.

### SUMMARY OF THE INVENTION

The present invention provides a deposition apparatus including a plurality of reaction chambers and a method of controlling the deposition apparatus, that results in a more efficient manufacturing processes and in less economic loss.

According to an aspect of the present invention, there is provided a deposition apparatus that includes a first chamber to deposit a first deposition material onto a deposition body, a second chamber to deposit a second and different deposition material onto the deposition body, a third chamber to deposit the first deposition material onto the deposition body, a transfer chamber connected to the first through third chambers, the transfer chamber to transfer the deposition body to ones of the first through third chambers and a control unit to transport the deposition body from the transfer chamber to ones of the first through third chambers. The control unit selectively transports the deposition body from the transfer chamber to one of the first chamber and the third chamber for deposition. the control unit to sequentially transport the deposition body from the transfer chamber to the first chamber and then to the third chamber so as to perform deposition of the first deposition material in both of the first and the third chambers.

According to another aspect of the present invention, there is provided a deposition apparatus that includes a plurality of deposition chambers to deposit different materials onto a deposition body, a preliminary chamber that is set under the same condition as one of the deposition chambers and a control unit that performs deposition by transferring the deposition body into one of the deposition chambers or the preliminary chamber. The control unit to perform deposition by putting the deposition body sequentially into the deposition chambers and the preliminary chamber.

According to another aspect of the present invention, there is provided a method of controlling a deposition apparatus, the method including providing a first chamber, a second chamber and a third chamber, setting the third chamber under the same deposition conditions as the first chamber, depositing a first deposition material onto a first deposition body arranged within the first chamber, depositing a second and different deposition material onto the first deposition body arranged within a second chamber, depositing the first deposition material onto a second deposition body arranged within one of the first chamber and the third chamber and depositing the second deposition material onto the second deposition body arranged within the second chamber.

The second deposition body can be arranged within the third chamber during said depositing said first deposition material onto said second deposition body while a deposition condition of the first chamber is being adjusted. The second deposition body can be arranged within the third chamber during said depositing said first deposition material onto said second deposition body while the first deposition material is being deposited onto the first deposition body arranged within the first chamber. The method can also include depositing the first deposition material onto the first deposition body arranged within the third chamber after the depositing of the first deposition material onto the first deposition body arranged within the first chamber.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic view illustrating a deposition apparatus according to an embodiment of the present invention;

FIG. 2 is a schematic view illustrating a reaction chamber included in the deposition apparatus of FIG. 1; and

FIGS. 3A and 3B is a flowchart illustrating a method of controlling a deposition apparatus according to a first embodiment of the present invention;

FIGS. 4A through 4C is a flowchart illustrating a method of controlling a deposition apparatus according to a second embodiment of the present invention; and

FIGS. 5A through 5C is a flowchart illustrating a method of controlling a deposition apparatus according to a third embodiment of the present invention.

### DETAILED DESCRIPTION OF THE INVENTION

An aspect of the present invention will now be described more fully with reference to the accompanying drawings, in which exemplary embodiments of the invention are shown. Like reference numerals in the drawings denote like elements, and thus their description will be omitted.

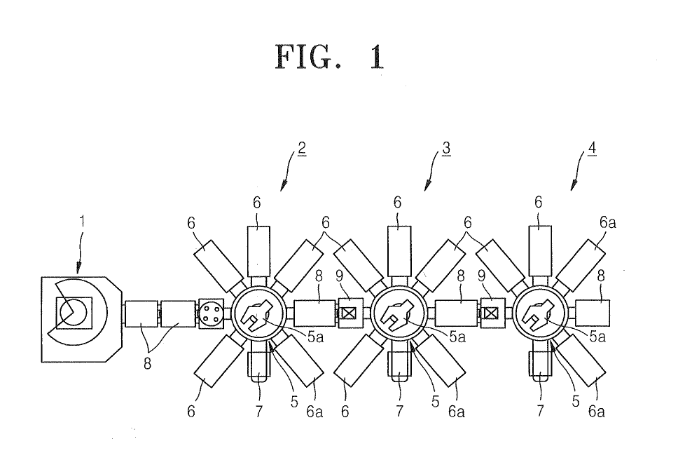

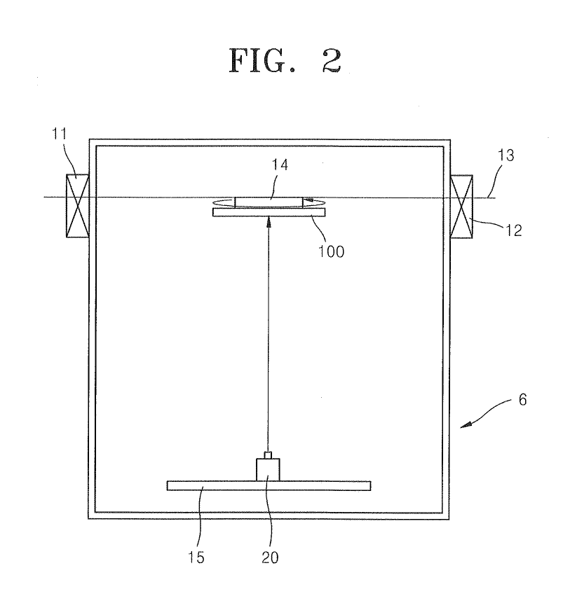

FIG. 1 is a schematic view illustrating a deposition apparatus according to an embodiment of the present invention, and FIG. 2 is a schematic view illustrating a reaction chamber 6 included in the deposition apparatus of FIG. 1.

As illustrated in FIG. 1, the deposition apparatus includes a deposition body supplying unit 1 that supplies a deposition body (or substrate° to manufacture an organic light emitting diode, and first through third clusters 2, 3, and 4 that process a deposition body transferred from the deposition body supplying unit 1 for each manufacturing process according to a deposition body deposition program stored in the deposition apparatus. In FIG. 1, the deposition apparatus includes three clusters, however the number of clusters is not limited thereto, and the deposition apparatus can have other numbers of clusters.

Each of the clusters 2, 3, and 4 includes a transfer chamber 5, at least one reaction chamber 6, a preliminary chamber 6a, and also a control unit (not shown) for controlling each of the elements of the first through third clusters 2, 3, and 4.

A transfer chamber 5 is located at a center of each of the first through third clusters 2, 3, and 4, and is connected to the reaction chambers 6. The deposition body is transported to the reaction chambers 6 via the transfer chamber 5, and the transfer chamber 5 includes a transferring instrument 5a that transfers the deposition body from one of the reaction chambers 6 to another one of the reaction chambers 6.

The control unit (not shown) transports the deposition body from the transfer chamber 5 to one of the reaction chambers 6 to perform deposition, thereby controlling the deposition apparatus overall.

In each cluster, at least one reaction chamber 6 is included, and is arranged around the transfer chamber 5. Different deposition sources are included in different reaction chambers 6, respectively, in order to deposit different deposition layers onto the deposition body. That is, while various reaction chambers 6 are illustrated in FIG. 1, none of the reaction chambers 6 includes the same deposition source.

The preliminary chamber 6a has the same structure and function as a reaction chamber 6, and at least one preliminary chamber 6a can be included in each cluster. The preliminary chamber 6a can be disposed between the reaction chambers 6, and the position thereof is not limited to the one illustrated in FIG. 1. The preliminary chamber 6a can be set to have identical process conditions as one of the reaction chambers 6. That is, the preliminary chamber 6a includes a deposition source which is the same as one or more of the deposition sources of the reaction chambers 6, thereby being able to replace any one of reaction chambers 6.

The structure of the reaction chamber 6 will be described below with reference to FIG. 2. As the preliminary chamber 6a has the same or similar structure as the reaction chamber 6, description thereof will be omitted. The reaction chamber 6 according to the present invention can include a structure in which a substrate supporting unit 14 rotates, as illustrated in FIG. 2, but is not limited thereto. For example, instead of or in addition to rotating, the substrate supporting unit can be moved or can translate across the deposition chamber and still be within the scope of the present invention.

The reaction chamber 6 is maintained in a vacuum, and can include an inlet 11 at one side, and an outlet 12 at another side, and the substrate transportation unit 13 can be arranged to pass through the reaction chamber 6 via the inlet 11 and the outlet 12.

The substrate supporting unit 14 can be mounted on the substrate transportation unit 13 so as to be rotatable by itself, and a substrate 100 (or deposition body) on which a deposition material is to be deposited can be transported into the reaction chamber 6 by using the substrate transportation unit 13. Then the substrate 100 is mounted onto and supported by the substrate supporting unit 14 within the reaction chamber 6. The substrate supporting unit 14 is installed separately from the substrate transportation unit 13 so as to be mounted within the reaction chamber 6.

In the reaction chamber 6, a deposition source 20, in which the deposition material is accommodated, heated, and gasified for deposition, is installed opposite to the substrate supporting unit 14. At least one deposition source 20 can be installed, including at least one deposition crucible accommodating a deposition material and a heating unit that heats the deposition crucible. The deposition source 20 can be installed on a mounting bar 15.

If only one reaction chamber for forming one deposition layer is included in a cluster, the entire cluster corresponding to the reaction chamber or the entire deposition apparatus has to be shut down and taken off-line when the reaction chamber is in need of periodic maintenance, or when the reaction chamber is being repaired due to a malfunction, or when the arrangement or speed of a substrate input into the reaction chamber becomes unstable. Accordingly, economic loss due to the above factors can become sizable.

However, in one embodiment of the present invention, the deposition apparatus includes at least one preliminary chamber 6a for each cluster, which serves as a substitute for one of the reaction chambers 6 when a reaction chamber 6 is shut down for maintenance or repair, or when the reaction chamber malfunctions. In another embodiment of the present invention, preliminary chamber 6a can serve as a supplement to a reaction chamber 6, allowing for parallel processing where two separate substrates simultaneously undergo the exact same deposition process, thereby increasing throughput. In still another embodiment of the present invention, preliminary chamber 6a also serves as a supplement to reaction chamber 6, but allows a deposition layer of twice the thickness to be produced by processing the substrate in process chamber 6 and subjecting the same substrate to the same process in preliminary chamber 6a. Thus, by including a preliminary chamber 6a, the above possibilities and process strategies are possible, resulting in greater process flexibility while providing for improved throughput, reducing tool down time, and reducing economic loss due to down time.

However, when only one reaction chamber is in a cluster, throughput is limited as the number of organic light emitting diode panels that can be manufactured during a predetermined tact time is limited. Accordingly, a method and apparatus that maximizes throughput of organic light emitting diode panels per tact time is critical.

According to the present invention, one deposition can be performed in a plurality of chambers per tact time since the preliminary chamber 6a is included, thereby increasing throughput and productivity. In addition, the deposition apparatus according to the present invention can include in each chamber a stock chamber 7 for keeping masks. Also, two buffer chambers 8 can be arranged between the deposition body supplying unit 1 and the first cluster 2 and can be in charge of moving the deposition body. A buffer chamber 8 for movement of the deposition body from one cluster to another can also be disposed between two adjacent clusters, and a rotation buffer chamber 9 for rotation of the deposition body can be further included.

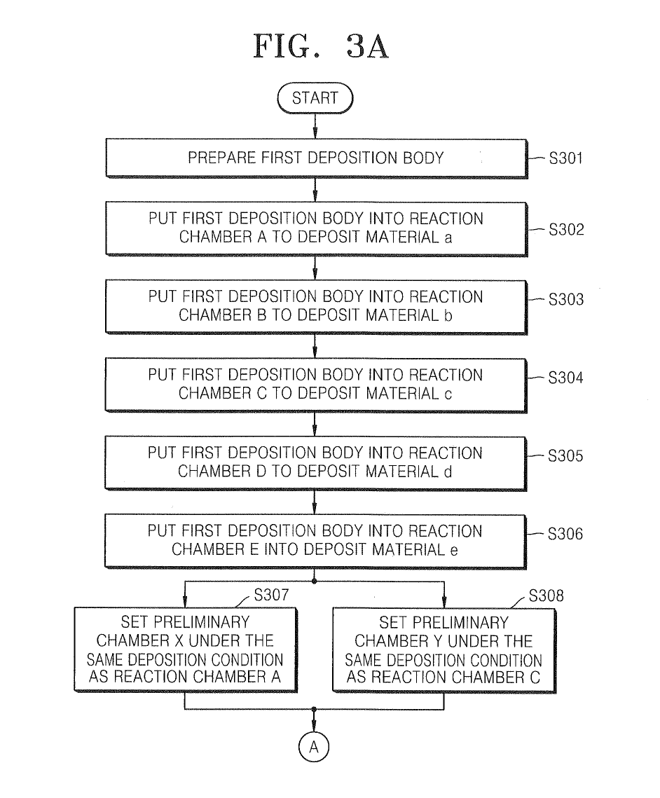

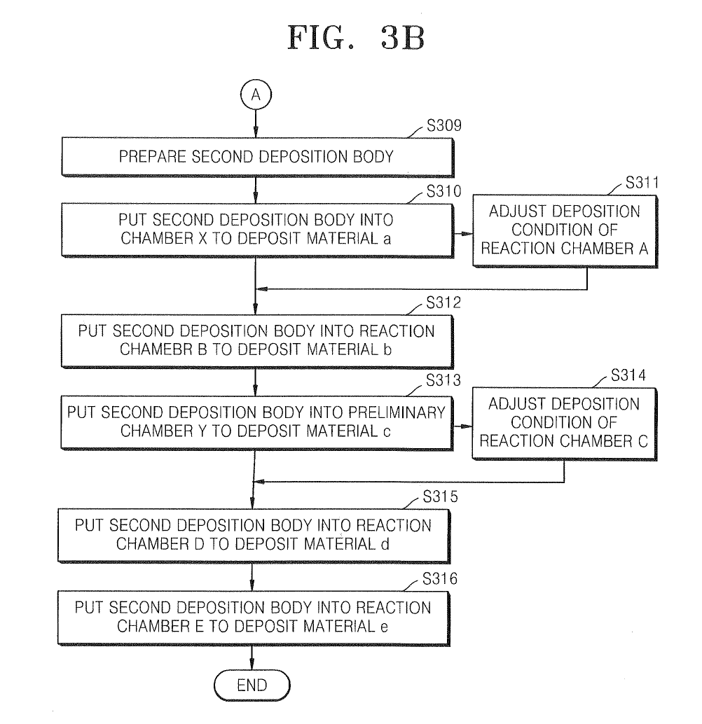

FIGS. 3 through 5 are flowcharts illustrating a method of controlling a deposition apparatus according to embodiments of the present invention. In Table 1 below, it is assumed that there are reaction chambers A through E, each including a deposition source for forming deposition layers a through e respectively, and that there are also preliminary chambers V, W, X, Y, and Z, each including a deposition source of one of the deposition layers a through e.

TABLE 1

| | | | | | |
|---|---|---|---|---|---|
| Type of deposition material | A | B | C | d | e |
| Type of reaction chamber | A | B | C | D | E |

| | |
|---|---|
| Type of preliminary chamber | V, W, X, Y, Z |

Referring to FIG. 3, in a method of controlling a deposition apparatus according to a first embodiment of the present invention, a preliminary chamber replaces a reaction chamber. In operation S301, a first deposition body is prepared. Pre-treatment processes such as washing and processing can be performed to the first deposition body before deposition is performed.

In operation S302, the first deposition body is put into a reaction chamber A to deposit a material a. In operation S303, the first deposition body including a deposition layer including the material a is supplied to reaction chamber B to deposit a layer including a material b. In operation S304, the first deposition body in which the deposition layers a and b are formed is put into a reaction chamber C to deposit material c, and in the same manner, in operations S305 and S306, the first deposition body is put into reaction chambers D and E, respectively, thereby sequentially depositing materials d and e.

In operations S307 and 308, a preliminary chamber X is set under the same deposition conditions as reaction chamber A, and a preliminary chamber Y is set under the same deposition conditions as the reaction chamber C. These operations include shaking off impurities from the reaction chambers X and Y, putting deposition sources to the preliminary chambers X and Y, replacing an anti-sticking substrate, and increasing the temperature of the deposition sources in order to perform deposition. The preliminary chambers X and Y are used when reaction chambers undergoes repair or periodic maintenance, such as replenishing a reaction chamber with deposition material, and so forth when the reaction chamber needs to be temporarily shut down and taken off line.

In operation S309, a second deposition body is prepared. In operation S310, the second deposition body is put into the reaction chamber X to deposit a deposition material a. In operation S311, while reaction chamber X deposits layer a on the second deposition body, testing, maintenance or repair work can be performed on chamber A, or chamber A can be used to produce a separate product line while chamber X is used as a substitute for chamber A.

In operation S312, the second deposition body, in which the material a has been deposited, is put into the reaction chamber B to deposit a material b. In operation S313, the second deposition material is then put into the preliminary chamber Y to deposit material c. In operation S314, while preliminary chamber Y deposits layer c on the second deposition body, testing, maintenance or repair work can be performed on chamber C, or chamber C can be used to produce a separate product line while preliminary chamber Y serves as a substitute for chamber C. In operation S315 and S316, the second deposition body is sequentially put into reaction chambers D and E to deposit materials d and e respectively.

As described above, if a particular reaction chamber is unusable, a preliminary chamber can be driven in place of the unusable reaction chamber by transferring a deposition body to the preliminary chamber. As a result, it is no longer necessary to shut down or take off-line an entire cluster when only a single reaction chamber within the cluster is unusable due to maintenance, repair, down-time, testing, or because the reaction chamber is serving to produce another product line.

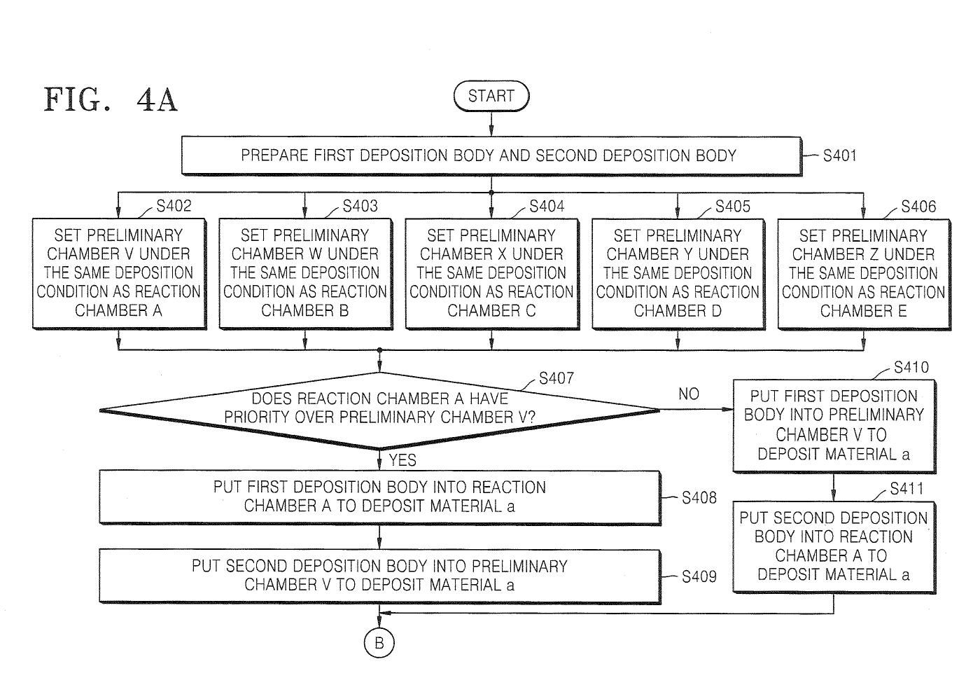

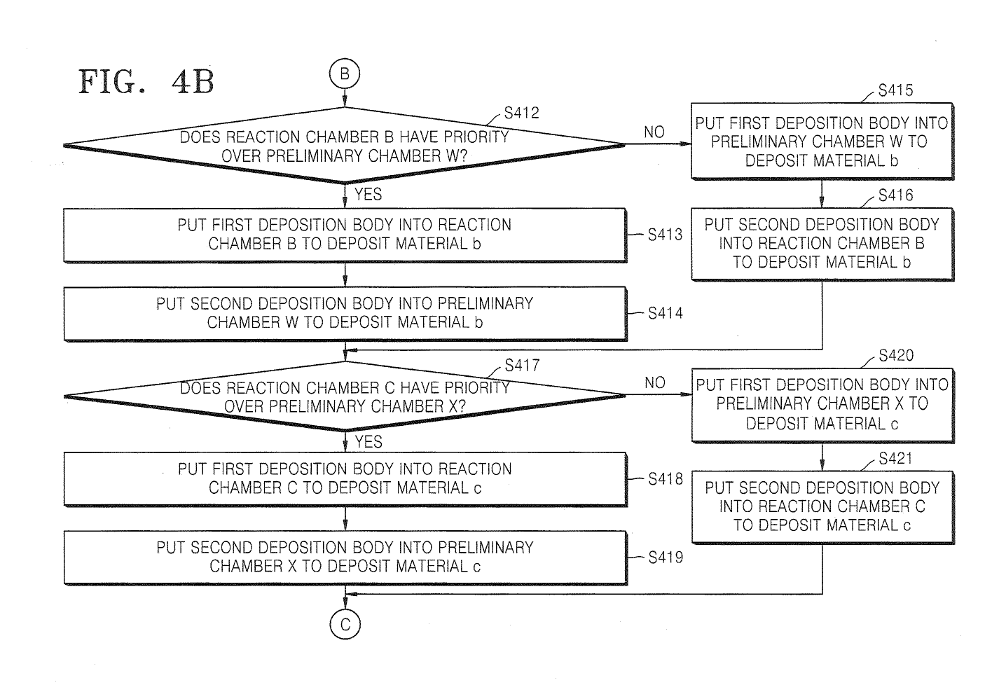

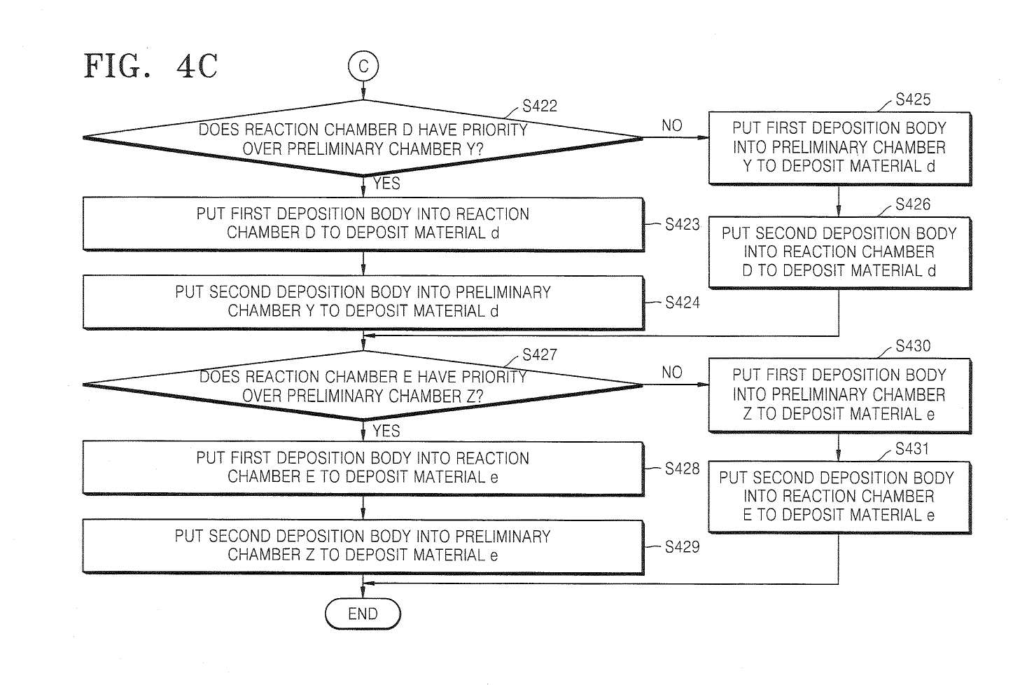

In a method of controlling a deposition apparatus according to another embodiment of the present invention illustrated in FIG. 4, a preliminary chamber and a reaction chamber are used at the same time, thereby performing deposition on more than one substrate at the same time. In operation S401, a first deposition body and a second deposition body are prepared. In operation S401, a plurality of deposition bodies can be prepared, and the number thereof is not limited to just two.

In operations S402 through S406, preliminary chambers V, W, X, Y, and Z are set under the same deposition conditions as reaction chambers A, B, C, D, and E, respectively. Thus, more than one chamber is capable of forming deposition layers a through e is provided.

In operation S407, the priority among the reaction chamber A and the preliminary chamber V, which are under the same deposition conditions, is determined. The priority refers to which of the chambers the first deposition body is to be first put into. The first deposition body can be designated by an engineer or can be a deposition body that has first arrived at a transfer chamber 5 among the plurality of deposition bodies. Among the plurality of chambers, a chamber that is ready-on first can have greater priority, or a predetermined chamber designated by the engineer can have greater priority.

In operation S408, if chamber A has greater priority than preliminary chamber V, the first deposition body is put into the reaction chamber A to deposit a material a. In operation S409, the second deposition body is put into the preliminary chamber V having lesser priority than the chamber A to deposit a material a.

In operation S410, if the preliminary chamber V has greater priority than the chamber A, the first deposition body is put into the preliminary chamber V to deposit a material a. In operation S411, the second deposition body is put into the reaction chamber A of lesser priority than the preliminary chamber V to deposit a material a.

In operation S412, the priority among the reaction chamber B and the preliminary W, which are under the same deposition conditions, is determined. In operations S413 and S414, if reaction chamber B has greater priority than preliminary chamber W, the first deposition body is put into the reaction chamber B and the second deposition body is put into the preliminary chamber W to respectively deposit a material b. In operations S415 and S416, if preliminary chamber W has greater priority than chamber B, the first deposition body is put into the preliminary chamber W and the second deposition body is put into the chamber B to respectively deposit a material b.

In operation S417, the priority among reaction chamber C and preliminary chamber X, which both are under the same deposition conditions, is determined, and the first deposition body is put into the chamber having greater priority to deposit material c in operations S418 through 5421.

The above process applies to the reaction chamber D and the preliminary chamber Y including a material d and the reaction chamber E and the preliminary chamber Z including a material e, as performed in operations S422 through S431, and thus repeated description thereof will be omitted.

Thus, as a plurality of chambers for forming a predetermined deposition layer are included according to the second embodiment of the present invention, deposition with respect to a plurality of substrates can be performed at the same time during an identical tact time, thereby increasing productivity.

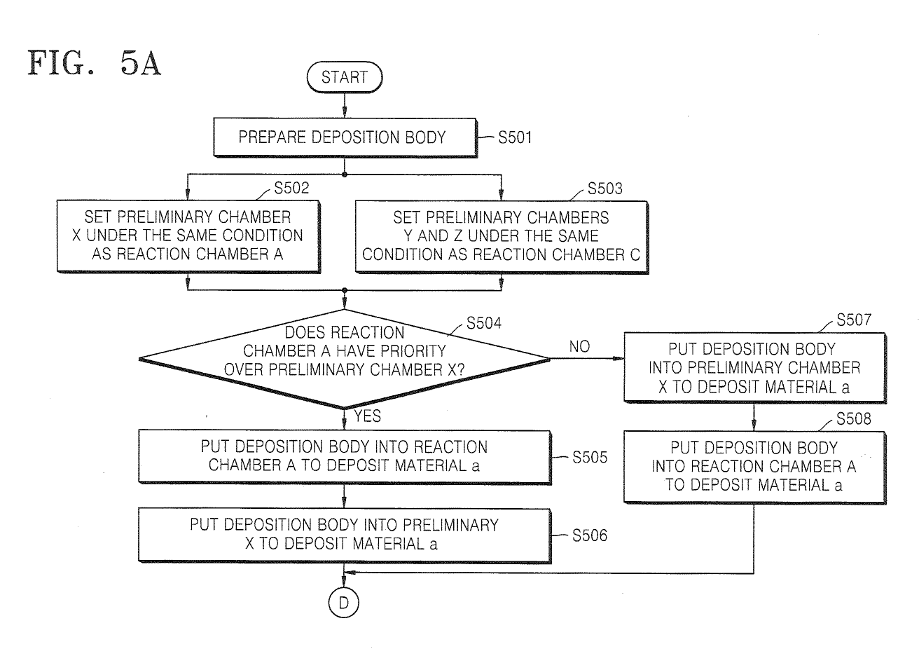

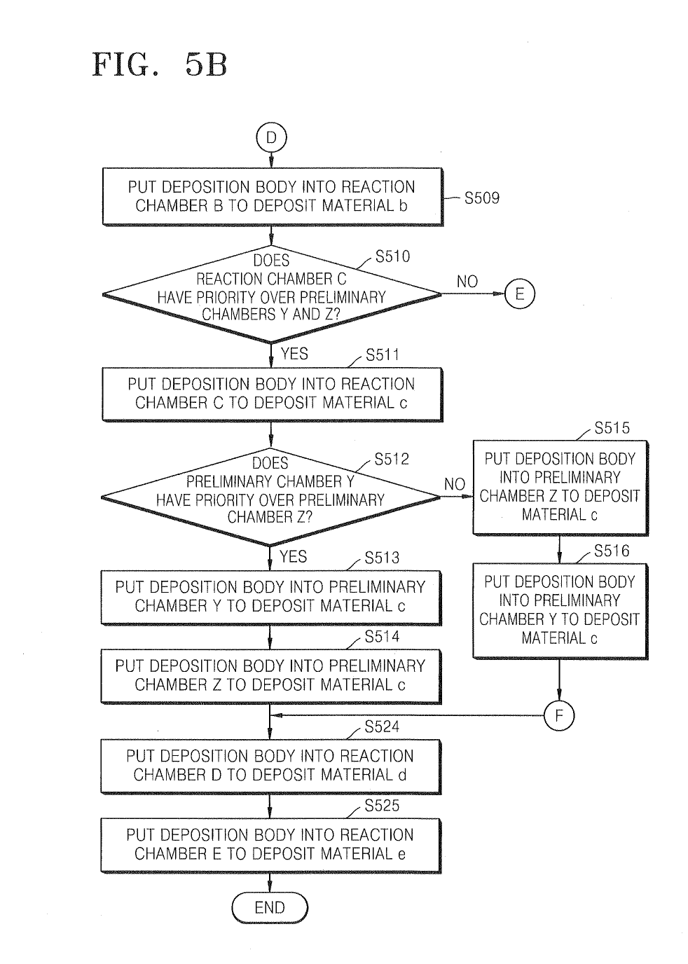

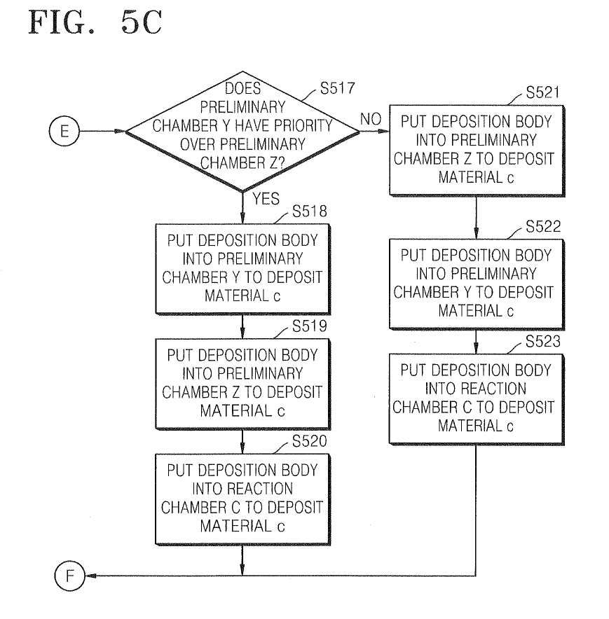

In a method of controlling a deposition apparatus according to another embodiment of the present invention illustrated in FIG. 5, a plurality of preliminary chambers and reaction chambers are used at the same time according to the thickness of a deposition layer. In operation S501, a deposition body is prepared. In operations S502 and S503, it is determined how many preliminary chambers are to be set under the same deposition conditions as various reaction chambers. The thickness of a predetermined deposition layer can be set and a preliminary chamber can be set according to the set thickness of the predetermined deposition layer.

According to the current embodiment of the present invention, the thickness of a deposition layer a is set to be twice the conventional thickness for the deposition layer a, and the thickness of a deposition layer c is set to be three times the conventional thickness for deposition layer c. In this case, the preliminary chamber X and the reaction chamber A are set under the same deposition conditions, and the preliminary chambers Y and Z and the reaction chamber C are set under the same deposition conditions.

However, the type of deposition samples and the thickness of the deposition layer are not limited to the example above, as deposition layers having various other thicknesses can also be formed by exchanging deposition sources in preliminary chambers and still be within the scope of the present invention.

In operation S504, it is determined which of the reaction chamber A and the preliminary chamber X has priority. Determining of the priority is the same as operation S407 except that here it is determined to which chamber the deposition body is to be put into first and which chamber will be used next. The conditions for putting the deposition body are the same as operation S407 and thus repeated descriptions will be omitted.

In operations S505 and S506, if the reaction chamber A has priority over the preliminary chamber X, the deposition body is first put into the reaction chamber A to deposit material a, and then the deposition body is put into the preliminary chamber X to further deposit material a. In operations S507 and S508, if the preliminary chamber X has priority over the reaction chamber A, the deposition body is first put into the preliminary chamber X and is later moved into reaction chamber A to complete the deposition of material a.

In operation S509, the deposition body including deposition layer a that is twice the thickness of a conventional deposition layer is put into the reaction chamber B to deposit a material b.

In operations S510 through S523, the deposition body is sequentially supplied to the reaction chamber C, the preliminary chamber Y, and the preliminary chamber Z according to the priority to form a deposition layer c having a thickness three times greater than a conventional deposition layer. Finally, in operations S524 through S525, a deposition body is put into the reaction chambers D and E to deposit materials d and e respectively.

Also, if only one reaction chamber 6 is used for one deposition, deposition time and deposition rate can be adjusted in order to form deposition layers having different thicknesses. For example, in order to form a deposition layer having a greater thickness, a substrate can instead be kept in the reaction chamber 6 for a longer period to produce a thicker layer, or can instead be placed in the reaction chamber 6 for a normal length of time but at an increased deposition rate to form a thicker than normal deposition layer. However, adjusting the thickness of the deposition layer by increasing the deposition time or the deposition rate is less efficient than increasing a tact time, and also, waste of the deposition body is intense.

According to the present invention, a plurality of chambers can be used to deposit one deposition layer, and thus a thickness of the deposition layer can be adjusted during an identical tact time, thereby reducing waste of a material and resulting in increased productivity and increased throughput.

While the present invention has been particularly shown and described with reference to exemplary embodiments thereof, it will be understood by those of ordinary skill in the art that the type or number of the above-described preliminary chambers or reaction chambers, or the type or number of deposition sources are not limited to the embodiments, and various changes in form and details can be made therein without departing from the spirit and scope of the present invention as defined by the following claims.

Other various examples other than the above-described embodiments can be possible within the scope of the appended claims of the present invention

What is claimed is:

1. A deposition apparatus, comprising:
a first chamber to deposit a first deposition material onto a deposition body;
a second chamber to deposit a second and different deposition material onto the deposition body;
a third chamber to deposit the first deposition material onto the deposition body;
a transfer chamber connected to the first through third chambers, the transfer chamber to transfer the deposition body to ones of the first through third chambers; and
a control unit to transport the deposition body from the transfer chamber to ones of the first through third chambers.

2. The deposition apparatus of claim 1, the control unit to selectively transport the deposition body from the transfer chamber to one of the first chamber and the third chamber for deposition.

3. The deposition apparatus of claim 1, the control unit to sequentially transport the deposition body from the transfer chamber to the first chamber and then to the third chamber so as to perform deposition of the first deposition material in both of the first and the third chambers.

4. A deposition apparatus, comprising:
a plurality of deposition chambers to deposit different materials onto a deposition body;
a preliminary chamber that is set under the same condition as one of the deposition chambers; and
a control unit that performs deposition by transferring the deposition body into one of the deposition chambers or the preliminary chamber.

5. The deposition apparatus of claim 4, wherein the control unit perfoi ns deposition by putting the deposition body sequentially into the deposition chambers and the preliminary chamber.

6. A method of controlling a deposition apparatus, the method comprising:
providing a first chamber, a second chamber and a third chamber;
setting the third chamber under the same deposition conditions as the first chamber;
depositing a first deposition material onto a first deposition body arranged within the first chamber;
depositing a second and different deposition material onto the first deposition body arranged within a second chamber;
depositing the first deposition material onto a second deposition body arranged within one of the first chamber and the third chamber; and
depositing the second deposition material onto the second deposition body arranged within the second chamber.

7. The method of claim 6, wherein the second deposition body is arranged within the third chamber during said depositing said first deposition material onto said second deposition body while a deposition condition of the first chamber is being adjusted.

8. The method of claim 6, wherein the second deposition body is arranged within the third chamber during said depositing said first deposition material onto said second deposition body while the first deposition material is being deposited onto the first deposition body arranged within the first chamber.

9. The method of claim 6, further comprising depositing the first deposition material onto the first deposition body arranged within the third chamber after the depositing of the first deposition material onto the first deposition body arranged within the first chamber,
wherein the second deposition body is also sequentially supplied to the first chamber and then to the third chamber for depositions of the first deposition material.
